(19) United States
(12) Patent Application Publication
(10) Pub. No.: US 2015/0230362 A1
(43) Pub. Date: Aug. 13, 2015

(54) ELECTRONIC COMPONENT FIXING STRUCTURE AND FIXING METHOD

(71) Applicant: Tomoyoshi Kobayashi, Aichi (JP)

(72) Inventor: Tomoyoshi Kobayashi, Aichi (JP)

(73) Assignee: OMRON AUTOMOTIVE ELECTRONICS CO., LTD., Aichi (JP)

(21) Appl. No.: 14/621,850

(22) Filed: Feb. 13, 2015

(30) Foreign Application Priority Data
Feb. 13, 2014 (JP) 2014-025948

(51) Int. Cl. H05K 7/20; H05K 3/30

(52) U.S. Cl. CPC H05K 7/2039; H05K 3/301

(57) ABSTRACT

An electronic component fixing structure includes: a mount; an electronic component mounted on the mount; and a fixing member which is formed of an elastic body and which fixes the electronic component to the mount. The mount includes: a mounting region on which the electronic component is mounted; an engaging surface which engages with the fixing member on a side opposite to a side on which the mounting region is positioned; and a wall which faces the mounting region and which is provided closer to an end surface of the mount than the mounting region. The fixing member includes: a pressing portion which presses the electronic component toward the mounting region; an engaging portion which engages with the engaging surface against a reactive force by the pressing portion; and a connection portion which is brought into contact with the wall between the pressing portion and the engaging portion.

### CROSS-REFERENCES TO RELATED APPLICATIONS

This application is based upon and claims the benefit of priority from Japanese Patent Application No. 2014-025948 filed on Feb. 13, 2014, the entire contents of which are incorporated herein by reference.

### FIELD

One or more embodiments of the present invention relates to an electronic component fixing structure and a fixing method of an electronic component to a mounting surface and, particularly, to an electronic component fixing structure and a fixing method of an electronic component to a heat sink member so as to efficiently transmit heat from an electronic component such as a field-effect transistor to the heat sink member.

### BACKGROUND

In the related art, a fixing device or the like has been known, in which an electronic component that emits heat is brought into contact with a heat sink member by using an elastic member and is attached to the heat sink member through as simple a manufacturing process as possible and thus the heat is sufficiently and reliably dissipated. For example, Japanese Unexamined Patent Application Publication No. 2005-191320 discloses a fixing device in which it is possible to further reliably position an electronic component while a short circuit of the electronic component is suppressed and flexibility of a manufacturing process is not lowered. The fixing device includes a heat sink block that has an engaging groove, an insulator block that has an accommodation unit which positions a power transistor interposed between the heat sink block and the insulator block, a locating groove and a locating pin which position the power transistor with respect to the heat sink block, and a clip of which one end and the other end are brought into contact with the engaging groove and the insulator block so as to pinch the heat sink block and the insulator block along with the power transistor interposed between the heat sink block and the insulator block.

In addition, Japanese Unexamined Patent Application Publication No. 2009-252810 discloses a heat sink for a heating element in which it is possible to mount a clip for performing close contact of a radiating surface of the heating element to a heat sink main body without using a jig. The heat sink includes a heat sink main body, a clip that has a pair of arms and is inserted into the heat sink main body along the radiating surface such that the radiating surface of the heating element and the heat sink main body are pinched to be brought into close contact with each other between the arms, and a guide plate that is disposed to have a gap from the heat sink which is less than a gap between the arms on the front side in a clip-inserted direction and which is greater than the gap between the arms on the depth side in the inserted direction. In the heat sink, the heat sink main body and the guide plate are formed integrally.

Japanese Unexamined Patent Application Publication No. 2002-198477 discloses a semiconductor device that is used for avoiding a state in which a semiconductor chip floats up when a screw or the like is loosened, a state in which cracking occurs on a resin of the semiconductor chip when a screw or the like is tightened excessively, or the like. In the semiconductor device, a fixing member such as a screw fixes an elastic member and the elastic member is brought into contact with the semiconductor chip on a surface opposite to a surface of the semiconductor chip which faces a heat sink member such that a compressive force is generated, and thus presses the semiconductor chip against the heat sink member with uniform surface pressure. An insulating sheet is disposed at a position separated from the fixing member such as a screw and there is no hole through which the fixing member such as a screw that causes an electrical short circuit passes.

### SUMMARY

According to the related art described above, there is a need to widen the elastic member that is the clip for pressing the electronic component such as a semiconductor element against a mounting surface in an assembly process, which requires time and effort. In addition, in order to perform fixing by inserting the elastic member from an end of a substrate, a long assembling stroke and a heavy load applied to the electronic component ensue and thus malfunctioning occurs. In addition, when the elastic member is fixed by using the screw or the like, a length of insulation becomes short, a region for a mounting surface is broadened, and the number of components is increased.

One or more embodiments of the invention provide a fixing structure and a fixing method in which an electronic component is easily attached to a mounting surface, it is difficult to release the component from the fixed state after the attachment, and a small projected area is obtained on a rear surface of a heat sink such that it is possible to efficiently perform heat dissipation.

According to one or more embodiments of the invention, there is provided an electronic component fixing structure including: a mount; an electronic component mounted on the mount; and a fixing member which is formed of an elastic body and which fixes the electronic component to the mount, wherein the mount includes: a mounting region on which the electronic component is mounted; an engaging surface which engages with the fixing member on a side opposite to a side on which the mounting region is positioned; and a wall which faces the mounting region and which is provided closer to an end surface of the mount than the mounting region, and wherein the fixing member includes: a pressing portion which presses the electronic component toward the mounting region; an engaging portion which engages with the engaging surface against a reactive force by the pressing portion; and a connection portion which is brought into contact with the wall between the pressing portion and the engaging portion.

With this configuration, since a jig for widening the fixing member is not needed when fixing the electronic component to the mount, time and effort are not spent and it is possible to provide a fixing structure in which, once the fixing is performed, it is not easy to release the component from the fixed state. In addition, since the assembling is performed in a direction perpendicular to a surface of the substrate, it is possible to provide a fixing structure in which an assembling stroke of the fixing member is short and a load on the electronic component is light. Further, since a component such as a screw is not used, a small mounting area is sufficient to mount the electronic component and thus it is possible to provide a fixing structure in which a projected area on a rear surface of a heat sink is small and it is possible to efficiently dissipate heat.

In the electronic component fixing structure, the engaging surface may be provided to form an angle with the end surface.

With this configuration, the engaging surface is the end of the mount and thus a complex mold such as a sliding mold is not needed for a mold for manufacturing the mount, which enables the manufacturing to be performed without much time and effort.

The electronic component fixing structure may further include a heat sink disposed at a position corresponding to the mounting region on the side opposite to the side on which the mounting region is positioned.

With this configuration, since the engaging surface that engages with the engaging portion is sufficiently small, it is possible to provide the fixing structure in which the heat sink is disposed on a surface on the rear side of the mounting region and thus heat dissipation efficiency is high.

The electronic component fixing structure may further include a slope extending from an end portion of the wall in a direction opposite to a side on which the mounting region is positioned toward a side separated from the mount.

With this configuration, the connection portion slides on the slope before coming into contact with the wall and thus it is possible to provide the fixing structure in which the fixing member is easily attached.

In the electronic component fixing structure, the fixing member may include one engaging portion and three pressing portions.

With this configuration, it is possible to attach three electronic components by using one fixing member.

According to one or more embodiments of the invention, there is provided a method of fixing an electronic component to a mount by using a fixing member formed of an elastic body, the method including: disposing the electronic component on a mounting region of the mount; disposing the fixing member, such that a pressing portion of the fixing member, which presses the electronic component toward the mounting region side, is brought into contact with the electronic component and such that an engaging portion which engages with a surface of the fixing member opposite to a surface on which the mounting region is positioned is brought into contact with an end surface of the mount; and pressing, until the engaging portion engages with the surface of the fixing member which is opposite to the surface on which the mounting region is positioned, the fixing member such that the engaging portion slides on the end surface and such that a connection portion between the pressing portion and the engaging portion slides on a wall which faces the mounting region and which is provided closer to the end surface of the mount than the mounting region.

With this method, since a jig for widening the fixing member is not needed when fixing the electronic component to the mount, time and effort are not spent and it is possible to provide a fixing method of the electronic component in which, once the fixing is performed, it is not easy to release the component from the fixed state. In addition, since the assembling is performed in a direction perpendicular to a surface of the substrate, it is possible to provide a fixing method in which an assembling stroke of the fixing member is short and a load on the electronic component is light.

The method of fixing an electronic component may further include: positioning an insulating sheet by placing one side of an insulating sheet to be brought into contact with the wall including two parts and disposing a protruding portion of the insulating sheet, which protrudes from the one side, between the two parts of the wall, and thereby positioning the insulating sheet.

With this method, it is possible to easily positioning the insulating sheet that is disposed between the electronic component and the mount.

As described above, according to one or more embodiments of the invention, it is possible to provide the fixing structure and the fixing method in which the electronic component is easily attached to the mounting surface, it is difficult to release the component from the fixed state after the attachment, and a small projected area is obtained on the rear surface of the heat sink such that it is possible to efficiently perform heat dissipation.

### BRIEF DESCRIPTION OF THE DRAWINGS

FIG. 1 is a plan view illustrating a fixing structure according to an embodiment of the invention;

FIG. 2A is a cross-sectional view illustrating the fixing structure taken along line A-A and FIG. 2B is a cross-sectional view illustrating the fixing structure taken along line B-B according to the embodiment of the invention;

FIG. 3A is a perspective view illustrating a mount when viewed from the upper left side on the front side and FIG. 3B is a perspective view illustrating the fixing structure when viewed from the upper left side on the front side according to the embodiment of the invention;

FIG. 4A is a perspective view illustrating the mount when viewed from the upper left side on the rear side, FIG. 4B is a perspective view illustrating the fixing structure when viewed from the upper left side on the rear side, and FIG. 4C is an enlarged view of portion C in a dotted line according to the embodiment of the invention;

FIG. 5A is a perspective view illustrating the mount when viewed from the lower left side on the front side, FIG. 5B is a perspective view illustrating the fixing structure when viewed from the lower left side on the front side, and FIG. 5C is an enlarged view of portion C in a dotted line according to the embodiment of the invention;

FIGS. 6A to 6G illustrate a fixing member according to the embodiment of the invention, in which FIG. 6A is a front view, FIG. 6B is a plan view, FIG. 6C is an undersurface view, FIG. 6D is a left side view, FIG. 6E is a right side view, FIG. 6F is a rear view, and FIG. 6G is a perspective view from the upper left side on the rear side;

FIG. 7 is a plan view of a substrate according to the embodiment of the invention; and

FIG. 8 is a component assembling view of the fixing structure according to the embodiment of the invention.

### DETAILED DESCRIPTION

Hereinafter, embodiments of the invention will be described with reference to the drawings. In embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid obscuring the invention.

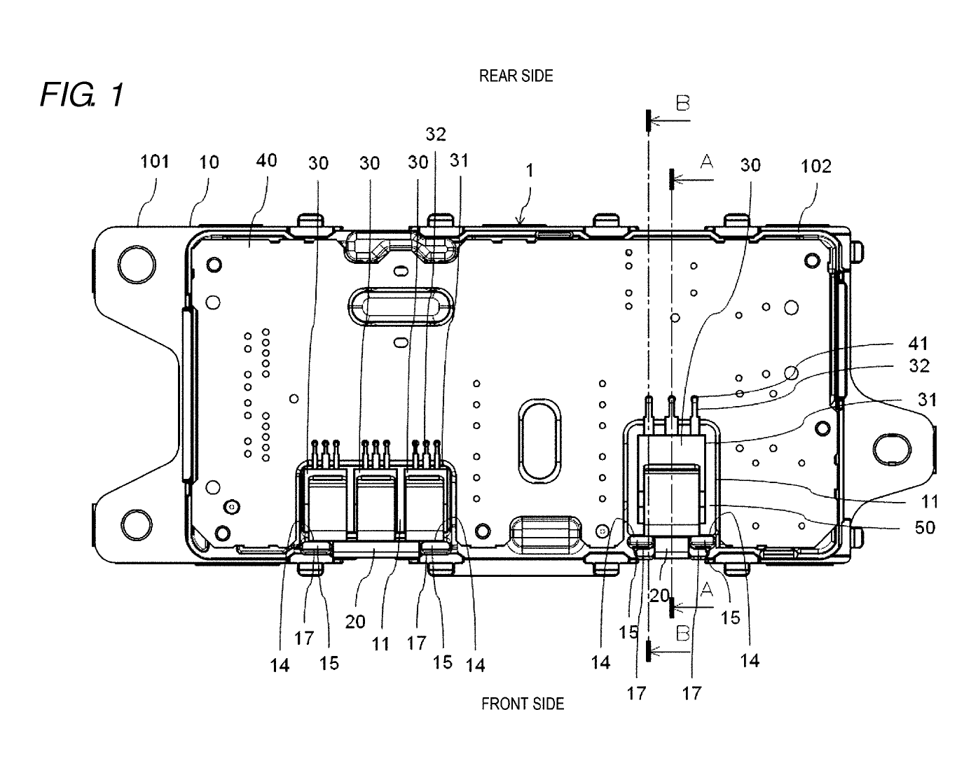

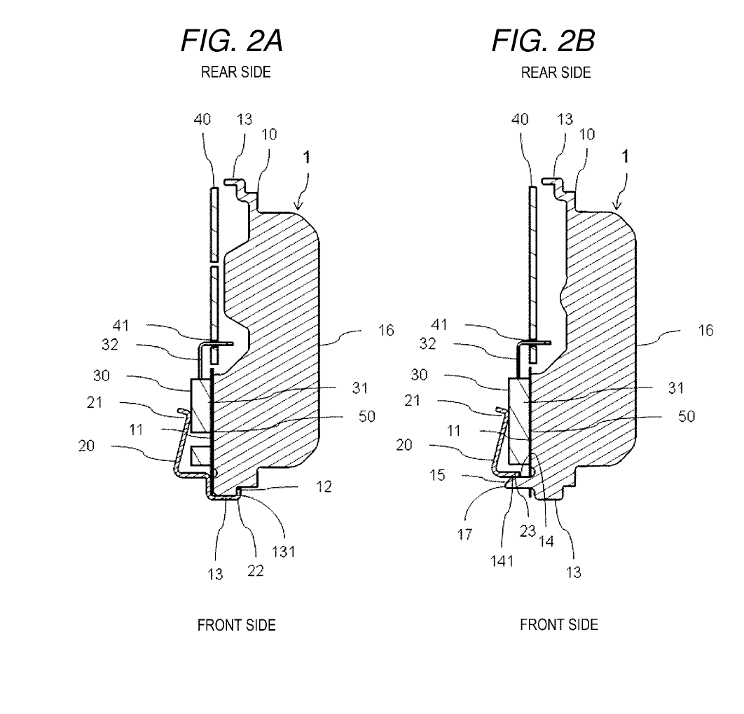

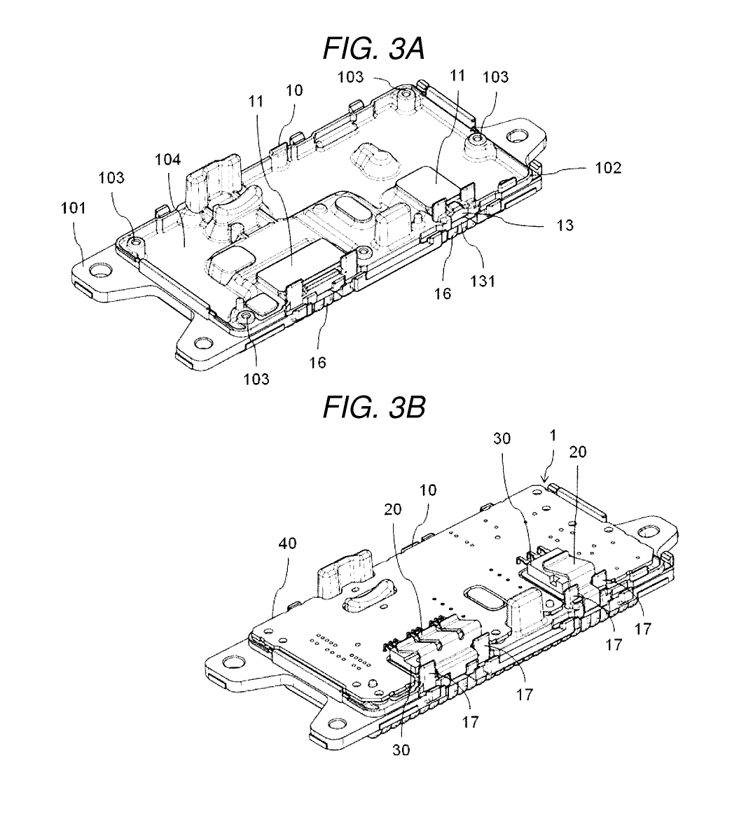

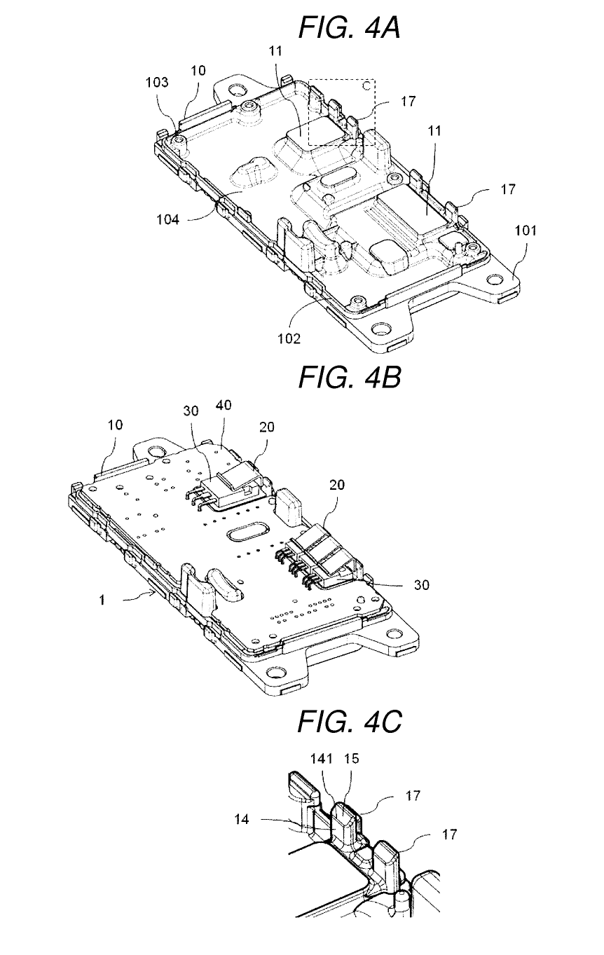

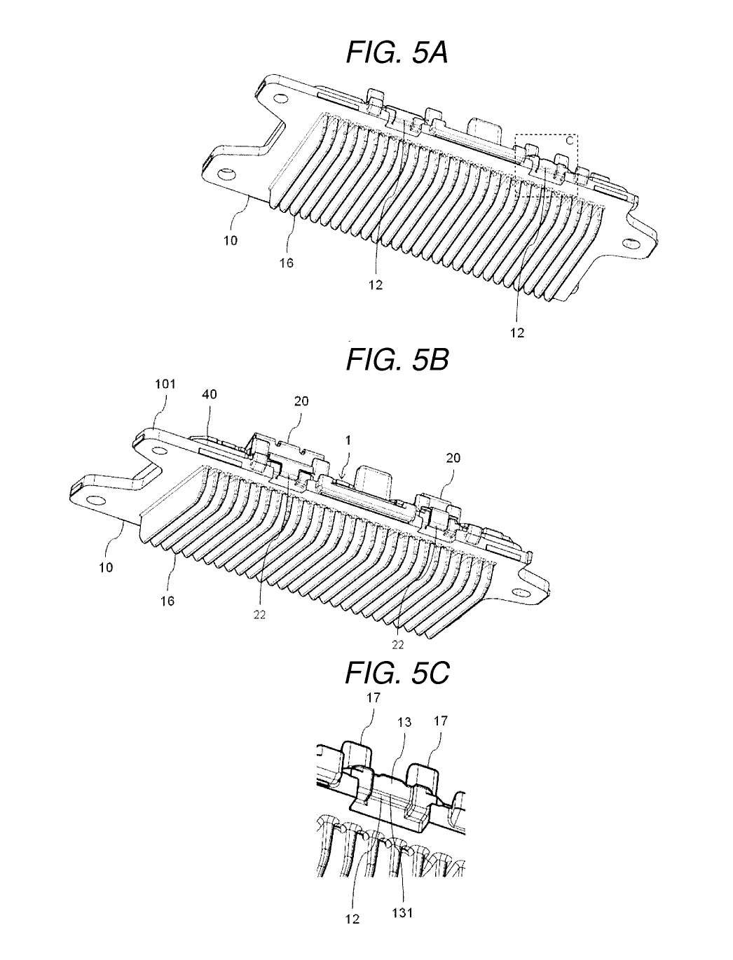

FIG. 1 is a plan view illustrating a fixing structure 1 according to the present embodiment. FIGS. 2A and 2B are cross-sectional views illustrating cross sections of the fixing structure 1 taken along lines A-A and B-B in FIG. 1. FIGS. 3A to 5C are perspective views illustrating the fixing structure (mount alone) before a substrate or the like is attached and the fixing structure after the substrate or the like is attached for easy understanding.

The fixing structure 1 includes a mount 10, an electronic component 30 mounted on the mount 10, a fixing member 20 that is formed of an elastic body and fixes the electronic component 30 to the mount 10, a substrate 40 which is connected electrically with the electronic component 30 and on which an electric circuit is formed, and an insulating sheet 50 that is disposed between the mount 10 and the electronic component 30 and electrically insulates both of the mount and the electronic component.

The mount 10 is prepared by using a metal material such as an aluminum material which is excellent in thermal conductivity through die casting and is formed integrally with a component of the mount 10 which will be described later. The mount 10 is substantially rectangular in a plan view so as to appropriately match an external shape of the substrate 40 except for attachment portions 101 (two on the left-side surface and one on the right-side surface), each of which has a hole for a bolt to attach a device or the like to which the fixing structure 1 is attached.

The electronic component 30 is an electronic component that includes a power element of a semiconductor chip which emits great heat. The power element includes, for example, a field effect transistor (FET), a power bipolar transistor (PBT), an insulated gate bipolar transistor (IGBT), and a power diode and, in addition, includes large scale integration (LSI) that includes a power circuit such as a switching regulator. In other words, any general-purpose products are included.

The electronic component 30 is configured to have a main body section 31 in which the semiconductor chip is disposed that has a thin rectangular parallelepiped shape formed of a resin material, and a plurality of (three) terminals 32 which stick out from the main body section 31. It is preferable that one surface of the main body section 31 to which the mount 10 is mounted be a surface with a wide area so as to secure a sufficient area that comes into contact with the mount 10. The other surface facing the surface of the main body section 31 to which mounting is performed does not need to be a flat surface because an assembling stroke as in the related art is not required at all, as will be described later.

On the top surface side (plan view side) of the mount 10, an upright outer-circumferential section 102 provided to surround the outer circumference of the substrate 40, two mounting regions 11, on which the electronic component 30 is mounted, in the vicinity of the upright outer-circumferential section 102 on the front side, two protruding portions 17 (total of four) for one mounting region 11 on the outer circumferential side of the mounting region 11, four substrate mounting holes 103 through which the substrate 40 is mounted in the vicinity of the upright outer-circumferential section 102, and a bottom section 104 which does not have a convex portion particularly at the central portion are provided.

On the undersurface side (undersurface view side) of the mount 10, many heat sinks 16 which extends downward in a substantially matching range to the substrate 40 on the top surface side, and an engaging surface 12 that engages with the fixing member 20 in the vicinity of an end surface 13 of the mount 10 at a position corresponding to the mounting region 11 on the top surface side are provided.

The mounting region 11 is brought into direct or indirect contact with the electronic component 30 that emits heat and transmits the heat from the electronic component 30 to the heat sinks 16 on the undersurface side of the mount 10. It is preferable that the surface of the mounting region 11 that comes into contact with the electronic component 30 come into close contact with the surface of the electronic component 30 on the attaching side (surface that comes into contact with the mounting region 11). In a case where a portion of the electronic component 30 with which the main body section 31 comes into contact is a flat surface, it is preferable that the surface of the mounting region 11 that comes into contact with the electronic component 30 be a flat surface. It is preferable that the size of the mounting region 11 be still greater than that of the portion with which the main body section 31 comes into contact such that it is possible to be in contact with the electronic component 30. In addition, in a case where a plurality of (for example, three) electronic components 30 are mounted on one mounting region 11, it is preferable that the size of the mounting region 11 be still greater than a total size of the main body sections 31 of the plurality of electronic components 30.

A basic thickness of the mount 10 from the bottom section 104 on the top surface side of the mount 10 to the rear side of the bottom section 104 except for the heat sinks 16 on the undersurface side is several millimeters and, in the mounting region 11, the thickness is increased to secure heat dissipation. The mounting region 11 has a hem that is widened from a mounting surface in a cone shape, thereby flowability of the die casting is improved, the heat is dispersed from the electronic component 30, and heat dissipation performance is improved.

The protruding portions 17 are provided at two positions, respectively, on the outer circumferential side of the mounting region 11 for one mounting region 11. The two protruding portions 17 are provided at positions corresponding to a width of the mounting region 11 in a front view. A part of the fixing member 20 (upper connection portion 24) which will be described later is provided to be inserted between the two protruding portions 17. According to the present embodiment, a shape of a cross section of the protruding portion 17 which is parallel to the surface of the substrate 40 is substantially a rectangle and a side surface of the protruding portion 17 is a flat surface; however, the cross-sectional shape of the protruding portion 17 may be an ellipse or the like instead of the rectangle and the side surface of the protruding portion 17 may be a curved surface.

The protruding portion 17 includes a wall 14 configured by a side surface on the mounting region 11 side and a slope 15 that extends from an end portion 141 on the upper side of the wall 14 in a direction opposite to the side on which the mounting region 11 is positioned toward a side separated from the mount 10. Since the wall 14 is formed on the substrate 40 side (toward the inner side) of the protruding portion 17, the wall 14 is formed to face the central portion side of the mount 10 (mounting region 11 side) on the outer circumferential side (closer to the end surface 13) of the mount 10 than the mounting region 11. The fixing member 20 which will be described later comes into contact with and slides on the wall 14 in the course of attaching to the mount 10 and the wall 14 is pressed due to an elastic force of the fixing member 20.

The slope 15 is formed to be widened from the wall 14 toward the upper side on the outer circumferential side. The wall 14 and the slope 15 are configured to form an angle on the end portion 141 on the upper side of the wall 14; however, the configuration is not limited thereto. A shape of a cross section of the protruding portion 17 which is perpendicular to the surface of the substrate 40 may be a tapered shape and the wall 14 and the slope 15 do not form an angle but form a series of smooth-curved surfaces. In this way, the part of the fixing member 20 (connection portion 23) slides on the slope 15 before coming into contact with the wall 14 and thereby the fixing member 20 is easily attached.

The engaging surface 12 is formed to engage with the part of the fixing member 20 which will be described later on the mount 10 side (undersurface side) opposite to the side on which the mounting region 11 is mounted. The engaging surface 12 may be provided at the central on the undersurface of the mount 10; however, it is preferable that the engaging surface 12 be provided in the vicinity of the end surface 13 of the mount 10, and, according to the present embodiment, it is further preferable that the engaging surface 12 be provided at the end of the undersurface of the mount 10 to form an angle with the end surface 13. Thus, the engaging surface 12 is provided at the end of the mount 10, thereby a complex mold such as a sliding mold is not needed for a mold for manufacturing the mount 10, which enables the manufacturing to be performed without much time and effort. The engaging surface 12 engages with a part of the fixing member 20 (engaging portion 22) in the last stage of the course in which the fixing member 20 is attached to the mount 10 and is pressed due to the elastic force of the fixing member 20. Since the engaging surface 12 engages with the fixing member 20 along with the end surface 13, an area is sufficiently small.

Although the heat sink 16 is also referred to as a heat dissipation fin, the heat sink 16 is a heat sink that is provided to dissipate heat from the electronic component 30, to improve efficiency of heat exchange, and to widen a heat transfer area and protrudes from the undersurface of the mount 10 in a plate shape. It is preferable that the heat sink 16 be provided even at a position corresponding to the mounting region 11 on the side opposite to the side where the mounting region 11 is positioned. This is because the heat from the electronic component 30 mounted on the mounting region 11 is easily dissipated. Since the engaging surface 12 with which the fixing member 20 (engaging portion 22) is engaged is sufficiently small, it is possible to provide the fixing structure 1 in which the heat sink 16 is provided on the surface on the rear side of the mounting region 11 and thus a good heat dissipation efficiency is achieved.

The upright outer-circumferential section 102 is fitted into a metal cover (not illustrated) which covers the substrate 40 so as to reduce a leakage of a radio wave and to prevent dust from infiltrating. The metal cover is attached through an attachment hole of the attachment portion 101 and is fastened with a bolt, and thereby a contact area between the mount 10 and the metal cover is widened, contact pressure is increased, and the ground is stabilized. A distance between the upright outer-circumferential section 102 and the outer circumference of the substrate 40 is set to have a certain extent of a creepage distance in order to prevent a wraparound of moisture.

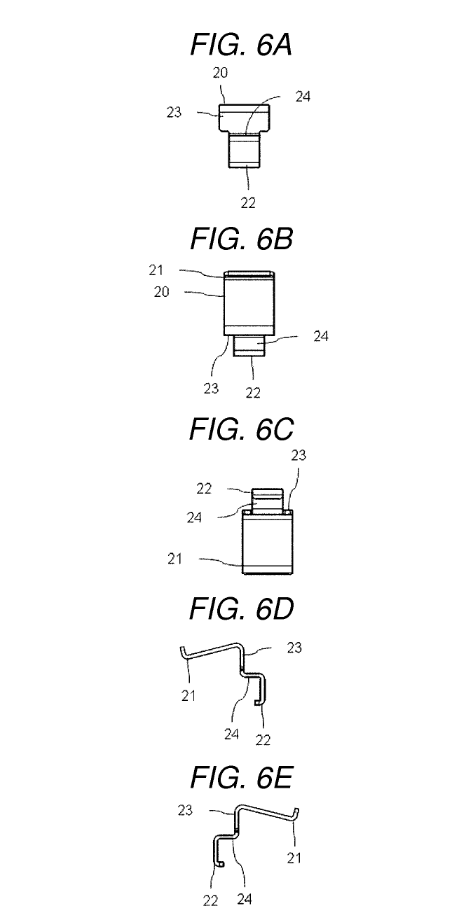

Here, the fixing member 20 is described also with reference to FIGS. 6A to 6G. The fixing member 20 is a member formed of an elastic body for fixing the electronic component 30 to the mount 10. The member formed of the elastic body is configured to have a flat spring formed of an elongated spring-like plate material, for example, a metal material such as high-carbon steel, stainless steel or a copper alloy and the fixing member 20 is formed by variously bending the flat spring.

The fixing member 20 includes a pressing portion 21 which is positioned at one end of the fixing member 20 and presses the electronic component 30 toward the mounting region 11, an engaging portion 22 which is positioned at the other end of the fixing member 20 and engages with the engaging surface 12 and comes into contact with the end surface 13 because the engaging portion 22 counters the reaction force by the pressing portion 21, a connection portion 23 that comes into contact with the wall 14 between the pressing portion 21 and the engaging portion 22, and an upper connection portion 24 that comes into contact with the upper side of the mount 10 between the connection portion 23 and the engaging portion 22.

The pressing portion 21 is formed by bending a portion slightly separated from one end of the fixing member 20 substantially at the right angle (first bending). There is no need to form the pressing portion 21 by bending in such a way, and the one end itself of the fixing member 20 is used as the pressing portion. Since a corner of the one end fixing member 20 presses the electronic component 30 toward the mounting region 11 side causes the electronic component 30 to be damaged, it is preferable to form the pressing portion by bending in such a way.

The connection portion 23 is formed by bending a portion between the pressing portion 21 and the connection portion 23 at an angle equal to or more than the right angle in a direction opposite to the bending direction of the pressing portion 21. The bending portion (second bending) is bent at the angle equal to or more than the right angle and thereby it is possible for the pressing portion 21 to press the electronic component 30 from the top toward the mounting region 11 side. The length from the pressing portion 21 to the bending portion depends on the size of the electronic component 30 that is mounted. The connection portion 23 is a wider width than the upper connection portion 24 which will be described later or the engaging portion 22. The connection portion 23 is formed to have the wider width than the upper connection portion 24 and thereby the connection portion 23 comes into contact with the wall 14 or the slope 15 when the upper connection portion 24 is inserted into a portion between the protruding portions 17.

The upper connection portion 24 is formed (third bending) by bending a portion between the connection portion 23 and the upper connection portion 24 substantially at the right angle in a direction opposite to the bending direction of the bending portion (second bending) described above which is bent at the angle equal to or more than the right angle. A distance from the bending portion (second bending) described above which is bent at the angle equal to or more than the right angle to the bending portion (third bending) is equal to or more than the thickness of the mounted electronic component 30 and is a distance in which a sufficient elastic force is produced such that the fixing member 20 that is a flat spring is deformed and fixed during fixing of the electronic component 30. As described above, since the upper connection portion 24 is formed to have a narrower width than the connection portion 23, it is easy to insert between two protruding portions 17 and thus the attachment is performed to be in contact with the top surface of the mount 10.

The engaging portion 22 is formed (fourth bending) by bending a portion substantially at the right angle in a direction opposite to the bending direction of the bending portion (third bending) by which the upper connection portion 24 is formed. A distance from the bending portion (third bending) by which the upper connection portion 24 described above is formed to the bending portion (fourth bending) is substantially the same as a distance from the wall 14 to the end surface 13 of the mount 10. The engaging portion 22 has a bending portion (fifth bending) which is bent substantially at the right angle in the same bending direction as that of the fourth bending. A distance from the bending portion (fourth bending) by which the engaging portion 22 is formed to the bending portion (fifth bending) is substantially the same as the thickness in the end surface 13 of the mount 10.

A distance from the bending portion (fifth bending) to the other end (tip of the engaging portion 22) of the fixing member 20 is substantially the same as the width of the engaging surface 12 such that the engaging portion 22 engages with the engaging surface 12 which is positioned on the surface on the undersurface side of the mount 10. When the fixing member 20 is attached to the mount 10, the engaging portion 22 comes into contact with the end surface 13 and engages with the engaging surface 12 such that the engaging portion 22 counters the reaction force from the electronic component 30 in the pressing portion 21 and the reaction force from the wall 14 in the connection portion 23. Since the distance from the fifth bending of the engaging portion 22 to the tip of the engaging portion 22 is short, the tip of the engaging portion 22 comes into contact with and slides on the end surface 13 when the fixing member 20 is attached to the mount 10. The fixing member may have one engaging portion and three pressing portions. In this case, it is possible to attach three electronic components by one fixing member.

As described above, the fixing structure 1 includes a mounting region 11 on which the electronic component 30 is mounted, the engaging surface 12 that engages with the fixing member 20 on the side opposite to the side on which the mounting region 11 is positioned, and the mount 10 that has the wall 14, which faces the mounting region 11, on the end surface 13 side of the mount 10 from the mounting region 11. In addition, the fixing structure 1 includes the fixing member 20 that has the pressing portion 21 that presses the electronic component 30 toward the mounting region 11, the engaging portion 22 that engages with the engaging surface 12 that counters the reaction force by the pressing portion 21, and the connection portion 23 that comes into contact with the wall 14 between the pressing portion 21 and the engaging portion 22 and is formed of the elastic body that fixes the electronic component 30 to the mount 10.

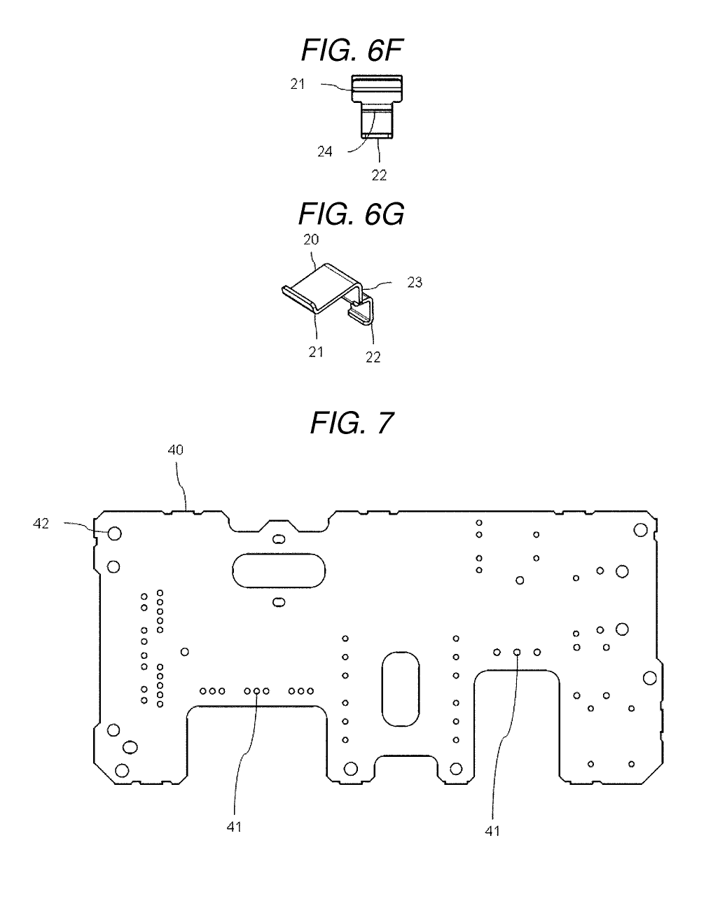

Here, the substrate 40 is described also with reference to FIG. 7. The substrate 40 has many through holes 41 through which a terminal such as the electronic component 30 or the electronic element is inserted and solder connection is performed, an electronic circuit (not illustrated) that connects these terminals electrically, and an attachment hole 42 for attaching the mount 10 by using a screw. In a case where the fixing structure 1 is used in AC-DC conversion, the fixing structure 1 has functions of converting an alternating current input from an AC power supply cable (not illustrated) through a high-pressure connector into a direct current of the predetermined voltage and outputting the converted direct current through the a low-pressure connector (not illustrated) to a DC power supply cable. The substrate 40 is not present at a portion corresponding to the mounting region 11 such that the electronic component 30 is brought into direct contact with the mount 10.

The insulating sheet 50 is positioned between the mounting region 11 of the mount 10 and the electronic component 30, electrically insulates both the mounting region 11 and the electronic component 30, and transfers the heat from the electronic component 30 to the mounting region 11. The insulating sheet 50 is configured to have a sheet prepared by a material, for example, a silicon resin, which is excellent in electrical insulation which is the thermal conductivity. It is preferable that the insulating sheet 50 further include flameproofness or a close contact property. Further, it is preferable that the insulating sheet 50 include a protrusion portion that protrudes from a certain side so as to be easily positioned.

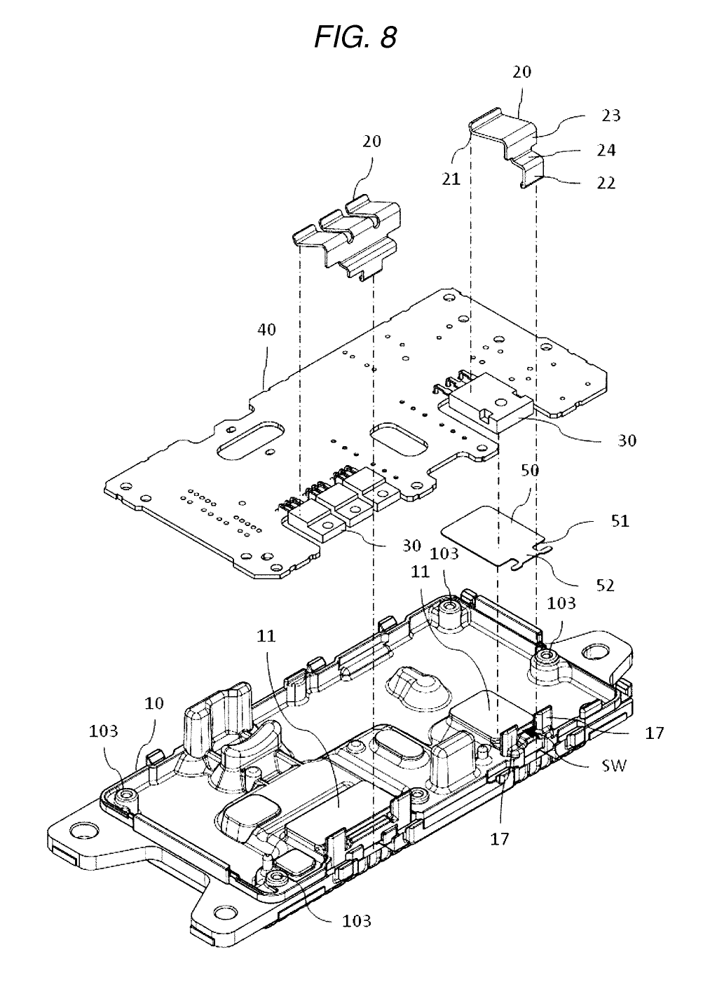

Next, with reference to FIG. 8, a method of fixing the electronic component 30 to the mount 10 by using the fixing member 20 in the fixing structure 1 described above is described. The electronic component 30 or the other elements which are required are all attached to the substrate 40 by soldering or the like.

In a case where the insulating sheet 50 is provided between the mounting region 11 and the electronic component 30, first the insulating sheet 50 is disposed on the mounting region 11. In this case, since the two walls 14 facing the mounting region 11 on the end surface 13 side of the mount 10 from the mounting region 11 are present, it is possible to position the insulating sheet 50 as follows. That is, one side 51 of the insulating sheet 50 comes into contact with the two walls 14, a protrusion 52 of the insulating sheet 50 protruding from the one side 51 is disposed at SW between the two walls 14, and thereby the insulating sheet 50 is positioned on the mounting region 11 vertically and horizontally. Thus, it is possible to easily position the insulating sheet 50 that is disposed between the electronic component 30 and the mount 10.

Next, the substrate 40 is attached to the mount 10. The substrate 40 is positioned on the top surface side of the mount 10 by bosses appropriately formed through die casting and is screw-fastened and fixed to the substrate mounting hole 103. Since the substrate 40 is not formed at the position, the electronic component 30 attached on the substrate 40 is disposed directly on the mounting region 11 or indirectly through the insulating sheet 50. Even though the electronic component 30 is disposed on and comes into contact with the mounting region 11 in this state, close contact is not performed.

Next, the fixing member 20 is disposed as follows. The fixing member 20 is disposed such that the upper connection portion 24 having a narrower width is disposed at SW between the two walls 14 which are between the two protruding portions 17. To be more specific, the upper connection portion 24 that has the narrower width is inserted so as to be interposed between the two protruding portions 17. In this way, the pressing portion 21 of the fixing member 20 that presses the electronic component 30 to the mounting region 11 side comes into contact with the electronic component 30. In addition, the tip of the engaging portion 22 of the fixing member 20 that is fitted with the surface opposite to the surface on which the mounting region 11 is positioned comes into contact with the end surface 13 of the mount 10. In addition, the connection portion 23 comes into contact with the end portion 141 on the slope 15 or the wall 14. The fixing member 20 is disposed in a stable state because the upper connection portion 24 is interposed between the protruding portions 17, the engaging portion 22 comes into contact with the end surface 13, and the connection portion 23 comes into contact with the slope 15.

Next, the fixing member 20 is attached to the mount 10 as follows. Then the electronic component 30 is fixed. The fixing member 20 disposed in such a stable state described above, is pressed by a force in a direction perpendicular to the surface of the substrate 40. In this way, the tip of the engaging portion 22 slides on the end surface 13 and the connection portion 23 between the pressing portion 21 and the engaging portion 22 slides on the wall 14, and thereby the portion between the engaging portion 22 and the connection portion 23 deforms relatively with reference to the connection portion 23. In addition, the absolute position of the pressing portion 21 is substantially unchangeable; however the connection portion 23 slides on the wall 14 and is moved, and thereby a portion between the pressing portion 21 and the connection portion 23 is deformed relatively with respect to the connection portion 23. The elastic deformation causes the electronic component 30 to be pressed to the mounting region 11 by the elastic force. The engaging portion 22 and the connection portion 23 slide on the end surface 13 and the wall 14 which are a part of the mount 10; however, the fixing member 20 is pressed by a force in the direction perpendicular to the surface of the substrate 40. Therefore, the pressing portion 21 does not slide on the electronic component 30, and thus the assembling stroke with reference to the electronic component 30 is short.

Further, when the fixing member 20 is pressed, and the tip of the engaging portion 22 passes through the end surface 13, the tip of the engaging portion 22 returns back to the connection portion 23 due to the elastic force of the fixing member 20. Therefore, the engaging portion 22 comes into contact with the end surface 13 and the engaging portion 22 is fitted to the surface of the mount 10 opposite to the surface on which the mounting region 11 is positioned. When the engaging portion 22 is engaged in this way, the release of the portion does not easily occur because of the effect of the elastic force of the fixing member 20.

In the method as described above, since a jig for widening the fixing member 20 is not needed when fixing the electronic component 30 to the mount 10, time and effort are not spent. Once the fixing is performed, it is not easy to release the component from the fixed state. In addition, since the assembling is performed in a direction perpendicular to a surface of the substrate, an assembling stroke of the fixing member 20 is short and a load on the electronic component 30 is light.

In addition, similarly, in the fixing structure 1 described above, since a jig for widening the fixing member 20 is not needed when fixing the electronic component 30 to the mount 10, time and effort are not spent. Once the fixing is performed, it is not easy to release the component from the fixed state. In addition, since the assembling is performed in a direction perpendicular to a surface of the substrate, the assembling stroke of the fixing member 20 is short and the load on the electronic component 30 is light. Further, since a component such as a screw is not used, a small mounting area is sufficient to mount the electronic component 30 and thus it is possible to provide a fixing structure in which a projected area on a rear surface of a heat sink is small and it is possible to efficiently dissipate heat.

The present invention is not limited to the exemplified embodiments and can be embodied in a configuration without departing from the details recited in each claim. That is, the present invention is illustrated in the drawings and described particularly related to specific embodiments mainly; however, it is possible for those skilled in the art to perform various modifications with reference to the embodiments described above in the number, material, or other detailed configurations without departing from the technical ideas and purposes of the present invention.

1. An electronic component fixing structure comprising:
a mount;
an electronic component mounted on the mount; and
a fixing member which is formed of an elastic body and which fixes the electronic component to the mount,
wherein the mount comprises:
a mounting region on which the electronic component is mounted;
an engaging surface which engages with the fixing member on a side opposite to a side on which the mounting region is positioned; and
a wall which faces the mounting region and which is provided closer to an end surface of the mount than the mounting region, and
wherein the fixing member comprises:
a pressing portion which presses the electronic component toward the mounting region;
an engaging portion which engages with the engaging surface against a reactive force by the pressing portion; and
a connection portion which is brought into contact with the wall between the pressing portion and the engaging portion.

2. The electronic component fixing structure according to claim 1,
wherein the engaging surface is provided to form an angle with the end surface.

3. The electronic component fixing structure according to claim 1, further comprising:
a heat sink disposed at a position corresponding to the mounting region on the side opposite to the side on which the mounting region is positioned.

4. The electronic component fixing structure according to claim 1, further comprising:
a slope extending from an end portion of the wall in a direction opposite to a side on which the mounting region is positioned toward a side separated from the mount.

5. The electronic component fixing structure according to claim 1,
wherein the fixing member comprises one engaging portion and three pressing portions.

6. A method of fixing an electronic component to a mount by using a fixing member formed of an elastic body, the method comprising:
disposing the electronic component on a mounting region of the mount;
disposing the fixing member, such that a pressing portion of the fixing member, which presses the electronic component toward the mounting region side, is brought into contact with the electronic component and such that an engaging portion which engages with a surface of the fixing member opposite to a surface on which the mounting region is positioned is brought into contact with an end surface of the mount; and
pressing, until the engaging portion engages with the surface of the fixing member which is opposite to the surface on which the mounting region is positioned, the fixing member such that the engaging portion slides on the end surface and such that a connection portion between the pressing portion and the engaging portion slides on a wall which faces the mounting region and which is provided closer to the end surface of the mount than the mounting region.

7. The method of fixing an electronic component according to claim 6, further comprising:
positioning an insulating sheet by placing one side of an insulating sheet to be brought into contact with the wall comprising two wall parts and disposing a protruding portion of the insulating sheet, which protrudes from the one side, between the two wall parts of the wall.
